(19) United States
(12) Patent Application Publication
(10) Pub. No.: US 2023/0369252 A1
(43) Pub. Date: Nov. 16, 2023

(54) SEMICONDUCTOR DEVICE AND METHOD OF MANUFACTURING THE SEMICONDUCTOR DEVICE

(71) Applicant: SK hynix Inc., Icheon-si (KR)

(72) Inventor: Jae Taek KIM, Icheon-si Gyeonggi-do (KR)

(73) Assignee: SK hynix Inc., Icheon-si Gyeonggi-do (KR)

(21) Appl. No.: 17/969,376

(22) Filed: Oct. 19, 2022

(30) Foreign Application Priority Data
May 16, 2022 (KR) 10-2022-0059302

(51) Int. Cl. H01L 23/60; H01L 27/11556; H01L 27/11526; H01L 27/11582; H01L 27/11573

(52) U.S. Cl. CPC H01L 23/60; H01L 27/11556; H01L 27/11526; H01L 27/11582; H01L 27/11573

(57) ABSTRACT

A semiconductor device includes a gate structure including conductive layers and insulating layers, which are alternately stacked, channel structures penetrating the gate structure, and contact plugs disposed under the gate structure and connected to the channel structures, respectively. The semiconductor device also includes a bit line connected to the channel structures through the contact plugs, a peripheral circuit disposed under the bit line, and a discharge interconnection that connects the bit line and the peripheral circuit.

### CROSS-REFERENCE TO RELATED APPLICATION

This application claims priority under 35 U.S.C. § 119(a) to Korean Patent Application No. 10-2022-0059302 filed on May 16, 2022, in the Korean Intellectual Property Office, which is incorporated herein by reference in its entirety.

### BACKGROUND

### 1. Technical Field

Embodiments relate to an electronic device and a method of manufacturing the same and, more particularly, to a semiconductor device and a method of manufacturing the semiconductor device.

### 2. Related Art

A degree of integration of semiconductor devices is basically determined by the area occupied by a unit memory cell. As the potential for improvement of the degree of integration of semiconductor devices in which memory cells are formed on a substrate in the form of a single layer reaches its limit, there is proposed a three-dimensional (3-D) semiconductor device in which memory cells are stacked on a substrate. Furthermore, in order to improve operational reliability of such semiconductor devices, various structures and manufacturing methods are being developed.

### SUMMARY

In an embodiment of the present disclosure, a semiconductor device may include a gate structure including conductive layers and insulating layers, which are alternately stacked, channel structures penetrating the gate structure, and contact plugs disposed under the gate structure and connected to the channel structures, respectively. The semiconductor device may also include a bit line connected to the channel structures through the contact plugs, a peripheral circuit disposed under the bit line, and a discharge interconnection that connects the bit line and the peripheral circuit.

In accordance with the present disclosure, a method of manufacturing a semiconductor device may include forming a peripheral circuit, forming a discharge interconnection connected to the peripheral circuit, forming a bit line connected to the discharge interconnection, forming contact plugs on the bit line, forming a stack on the contact plugs, forming openings that penetrate the stack and expose the contact plugs, respectively, and forming channel structures within the openings, respectively.

### BRIEF DESCRIPTION OF THE DRAWINGS

FIGS. 1A and 1B are block diagrams for describing structures of a semiconductor device according to an embodiment of the present disclosure.

FIGS. 2A to 2C are block diagrams for describing structures of a semiconductor device according to an embodiment of the present disclosure.

FIGS. 3A and 3B are diagrams illustrating structures of a semiconductor device for describing an embodiment of the present disclosure.

FIGS. 4A and 4B are diagrams for describing a semiconductor device according to an embodiment of the present disclosure.

FIGS. 5A and 5B are diagrams for describing a semiconductor device according to an embodiment of the present disclosure.

FIGS. 6A to 6G are diagrams for describing a method of manufacturing a semiconductor device according to an embodiment of the present disclosure.

### DETAILED DESCRIPTION

Hereinafter, embodiments according to the technical spirit of the present disclosure are described with reference to the accompanying drawings.

Some embodiments of the present disclosure may be directed to a semiconductor device having a stable structure and an improved reliability characteristic, and a method of manufacturing the semiconductor device.

According to the present technology, there can be provided a semiconductor device having a stable structure and improved reliability.

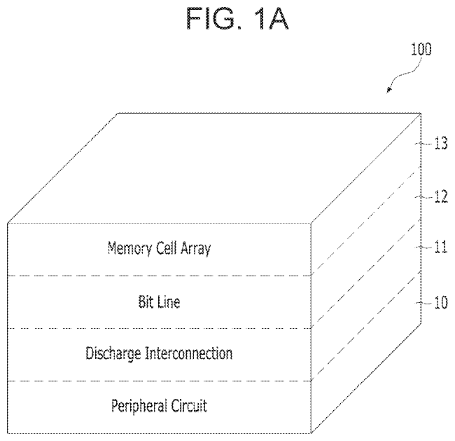

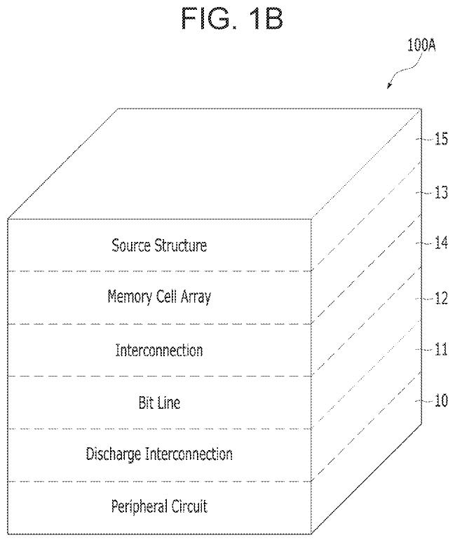

FIGS. 1A and 1B are block diagrams for describing structures of a semiconductor device according to an embodiment of the present disclosure.

Referring to FIG. 1A, a semiconductor device 100 may include a peripheral circuit 10, a discharge interconnection 11, a bit line 12, and/or a memory cell array 13, or may include different combinations of them.

The memory cell array 13 may include stacked memory cells. The memory cell array 13 may include a gate structure and a through structure that penetrates the gate structure. The gate structure may include stacked conductive lines. The conductive lines may include a word line, a selection line, etc. The through structure may include a channel structure, an electrode structure, etc. The memory cells may be disposed at locations where the through structure and the conductive lines are interconnected.

The bit line 12 may be disposed under the memory cell array 13. The bit line 12 may be connected to the through structure of the memory cell array 13. The peripheral circuit 10 may be disposed under the bit line 12. The peripheral circuit 10 may include a page buffer, a sense amplifier, a voltage generator, etc. The discharge interconnection 11 may be disposed between the peripheral circuit 10 and the bit line 12. The bit line 12 and the peripheral circuit 10 may be connected by the discharge interconnection 11.

The peripheral circuit 10, the discharge interconnection 11, the bit line 12, and the memory cell array 13 may be sequentially stacked. In a process of manufacturing the semiconductor device 100, the peripheral circuit 10 may be first formed, and the discharge interconnection 11, the bit line 12, and the memory cell array 13 may be then formed. When the memory cell array 13 is formed, the discharge interconnection 11 and the peripheral circuit 10 may be used as a charge discharge passage.

For reference, the semiconductor device 100 may be formed by using a wafer bonding method. For example, after a cell chip including the memory cell array 13 and a peripheral circuit chip including the peripheral circuit 10 are separately formed, the cell chip and the peripheral circuit chip may be bonded together. The bit line 12 and the discharge interconnection 11 may be included in the cell chip or may be included in the peripheral circuit chip. Alternatively, the discharge interconnection 11 may be manufactured as a separate interconnection chip, and the peripheral circuit chip, the interconnection chip, and the cell chip may be bonded together.

Referring to FIG. 1B, a semiconductor device 100A may include a peripheral circuit 10, a discharge interconnection 11, a bit line 12, and/or a memory cell array 13, or may include different combinations of them. The semiconductor device 100A may further include an interconnection 14 and/or a source structure 15.

The interconnection 14 may be disposed between the bit line 12 and the memory cell array 13. The memory cell array 13 and the bit line 12 may be electrically connected by the interconnection 14.

The source structure 15 may be disposed over the memory cell array 13. The memory cell array 13 may be connected between the source structure 15 and the bit line 12.

The peripheral circuit 10, the discharge interconnection 11, the bit line 12, the interconnection 14, the memory cell array 13, and the source structure 15 may be sequentially stacked and may be sequentially formed. For reference, after a plurality of chips is respectively manufactured, the semiconductor device 100A may be formed by a wafer bonding method.

According to the aforementioned structure, the bit line 12, the discharge interconnection 11, and the peripheral circuit 10 may be disposed under the memory cell array 13. Furthermore, when the semiconductor device 100, 100A is manufactured, the bit line 12, the discharge interconnection 11, and the peripheral circuit 10 may be used as a charge discharge passage.

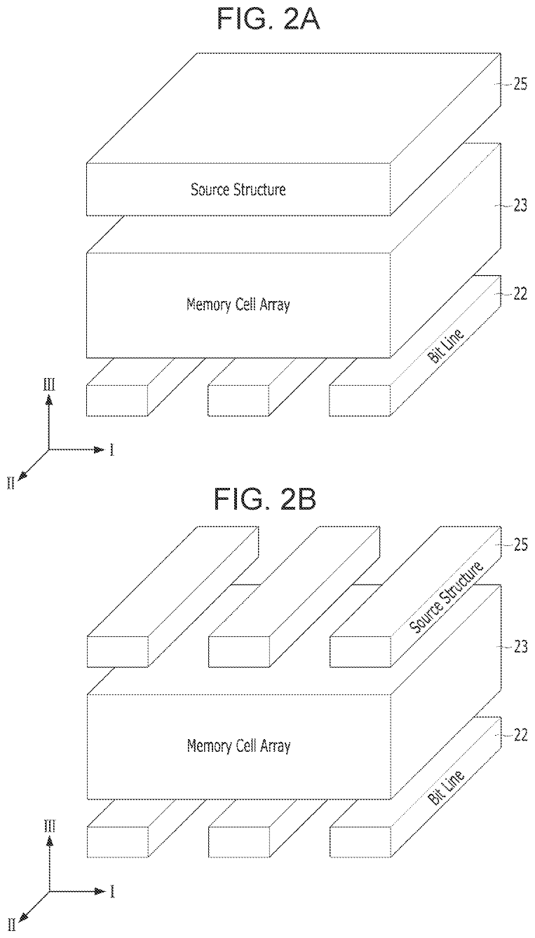

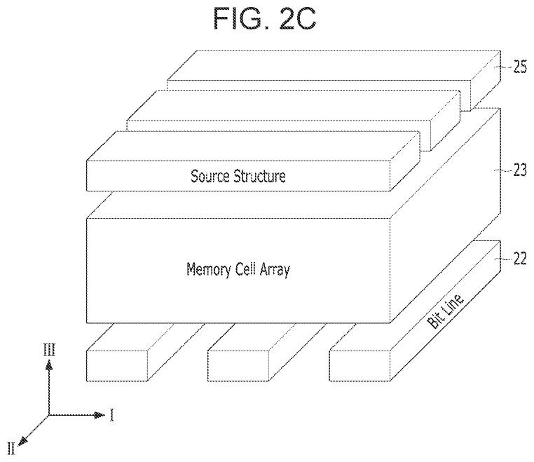

FIGS. 2A to 2C are block diagrams for describing structures of a semiconductor device according to an embodiment of the present disclosure. Hereinafter, contents redundant with the aforementioned contents are omitted and not described.

Referring to FIGS. 2A to 2C, the semiconductor device may include bit lines 22, a memory cell array 23, or a source structure 25, or may include a combination of them.

The bit lines 22 may be disposed under the memory cell array 23. The bit lines 22 may be arranged in a first direction I. The bit lines 22 may be extended in a second direction II that directionally intersects the first direction I. Intersecting directions represent different directions. In some instances, for example, intersecting directions may represent orthogonal directions.

The source structure 25 may be disposed over the memory cell array 23. The memory cell array 23 may be connected between the source structure 25 and the bit lines 22. The bit lines 22, the memory cell array 23, and the source structure 25 may be stacked in a third direction III that directionally intersects the first direction I and the second direction II. For example, the bit lines 22, the memory cell array 23, and the source structure 25 may be sequentially stacked and may be sequentially formed.

The source structure 25 may have various forms, such as a plate or a line. Referring to FIG. 2A, the source structure 25 has a plate form that extends in the first direction I and the second direction II.

Referring to FIG. 2B, each of source structures 25 has a line form. The source structures 25 may be arranged in a first direction I and may extend in a second direction II. The source structures 25 may be parallel to bit lines 22 that are arranged in the first direction I. The source structures 25 and the bit lines 22 may be disposed in a way to be overlapped in a third direction III, may be disposed in a way to go crisscross with respect to each other so that the source structures 25 and the bit lines 22 are not overlapped, or may be disposed in a way to be partially overlapped.

Referring to FIG. 2C, source structures 25 may be arranged in a second direction II and may extend in a first direction I. The source structures 25 may directionally intersect bit lines 22 that are arranged in the first direction I.

The bit lines 22, a memory cell array 23, and the source structures 25 may be sequentially stacked and may be sequentially formed in a third direction III that directionally intersects the first direction I and the second direction II.

According to the aforementioned structures, the memory cell array 23 may be disposed between the source structure 25 and the bit line 22. The source structure 25 may be changed depending on a form of the memory cell array 23, a form of the interconnection, etc. The form of the source structure 25 may be a plate form, a line form, etc.

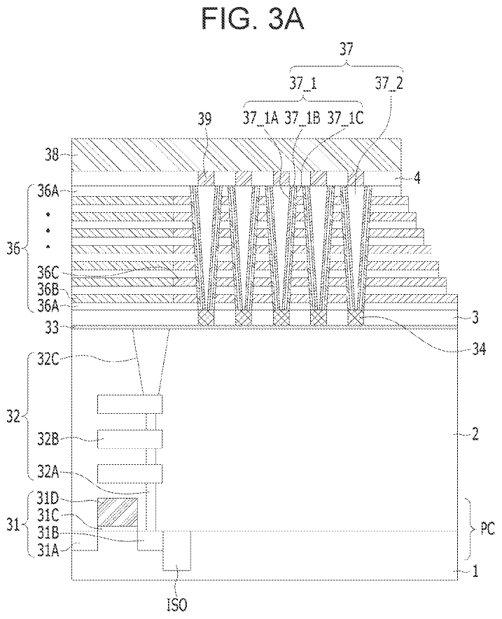

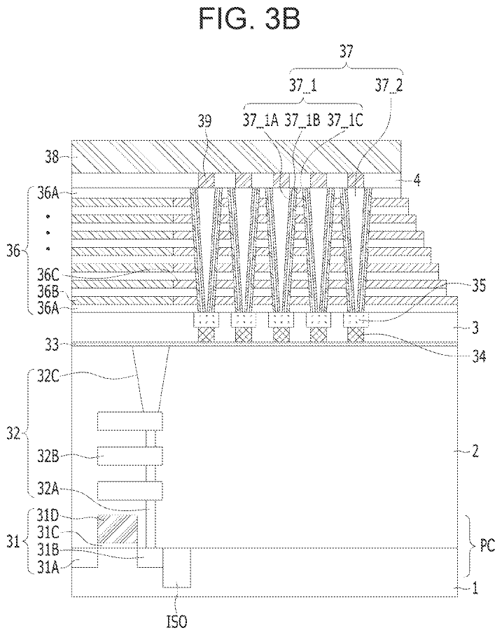

FIGS. 3A and 3B are diagrams illustrating structures of a semiconductor device for describing an embodiment of the present disclosure. Hereinafter, contents redundant with the aforementioned contents are omitted and not described.

Referring to FIG. 3A, the semiconductor device may include a peripheral circuit PC, a discharge interconnection 32, a bit line 33, first contact plugs 34, a gate structure 36, and/or channel structures 37, or may include a combination of them. The semiconductor device may further include a source structure 38, second contact plugs 39, and/or an isolation layer ISO, or may further include a combination of them.

The peripheral circuit PC may be disposed on a substrate 1. The substrate 1 may be a semiconductor substrate, such as a silicon wafer, a SiGe wafer, or an SOI wafer. The isolation layer ISO may be disposed within the substrate 1, and an active area may be defined by the isolation layer ISO. The peripheral circuit PC may include a transistor 31, a capacitor, a register, etc. The peripheral circuit PC may include a page buffer. The page buffer may temporarily store data that is received through the bit line 33 or may sense a voltage or current of the bit line when a read operation or a verification operation is performed.

The transistor 31 may be included in the page buffer and may be a high voltage transistor. For example, the transistor 31 may include a first junction 31A, a second junction 31B, a gate insulating layer 31C, and/or a gate electrode 31D. The gate electrode 31D may be disposed over the substrate 1. The gate electrode 31D may include a conductive material. The first junction 31A and the second junction 31B may be disposed within the substrate 1 on both sides of the gate electrode 31D. The first junction 31A and the second junction 31B may include n type or p type impurities. The gate insulating layer 31C may be disposed between the gate electrode 31D and the substrate 1. The gate insulating layer 31C may include an insulating material, such as oxide or nitride. The bit line 33 and an active area of the transistor 31 may be connected by the discharge interconnection 32. For example, the bit line 33 and the first junction 31A or the second junction 31B may be connected.

The discharge interconnection 32 may be disposed on the peripheral circuit PC. The discharge interconnection 32 may be connected to the peripheral circuit PC. For example, the discharge interconnection 32 may be connected to a high voltage transistor of the page buffer. The discharge interconnection 32 may be disposed within a first interlayer insulating layer 2. The discharge interconnection 32 may include contact plugs 32A, wires 32B, or a connection pad 32C. The discharge interconnection 32 may include a conductive material, such as aluminum, copper, or tungsten. The first interlayer insulating layer 2 may include an insulating material, such as an oxide or nitride.

The bit line 33 may be disposed on the discharge interconnection 32. The peripheral circuit PC may be disposed under the bit line 33. The bit line 33 may be connected to the peripheral circuit PC through the discharge interconnection 32.

The gate structure 36 may be disposed on the bit line 33. The gate structure 36 may include an insulating layer 36A and a conductive layer 36C. For example, the gate structure 36 may include the insulating layers 36A and conductive layers 36C that are alternately stacked. Sacrificial layers 36B may be left without being substituted with the conductive layers 36C in a manufacturing process. The sacrificial layers 36B and the conductive layers 36C may be disposed in levels in which the sacrificial layers and the conductive layers correspond to each other. The conductive layer may be a word line or a selection line.

An interconnection may be disposed on the bit line 33. The interconnection may include the first contact plugs 34. For example, the first contact plugs 34 may be disposed on the bit line 33. The first contact plugs 34 may be connected to the bit line 33. The first contact plugs 34 may be disposed within a second interlayer insulating layer 3. The first contact plug 34 may include a conductive material, such as aluminum, copper, or tungsten. The second interlayer insulating layer 3 may include an insulating material, such as an oxide or nitride.

The channel structures 37 may be disposed on the bit line 33. Each of the channel structures 37 may penetrate the gate structure 36. Each of the channel structures 37 may be connected to the bit line 33 through the gate structure 36. For example, each of the channel structures 37 may be connected to the bit line 33 through the first contact plug 34. The first contact plugs 34 may be disposed between the channel structures 37 and the bit line 33.

The channel structure 37 may include a channel layer 37_2 that penetrates the gate structure 36. Although not illustrated in this drawing, the channel structure 37 may further include an insulating core within the channel layer 37_2. The channel structure 37 may further include a memory layer 37_1 that surrounds the sidewall of the channel layer 37_2. The channel layer 37_2 may include a semiconductor material, such as silicon, or germanium. The memory layer 37_1 may include a tunneling layer 37_1A, a data storage layer 37_1B, and/or a blocking layer 37_1C, or may include a combination of them.

For reference, the semiconductor device may include electrode structures instead of the channel structures 37. The electrode structure may include an electrode layer that penetrates the gate structure 36, and may further include a memory layer that surrounds the external wall or internal wall of the electrode layer. The memory layer may include a variable resistance material.

The source structure 38 may be disposed over the channel structures 37. The second contact plugs 39 may be disposed between the source structure 38 and the channel structures 37. The source structure 38 may be connected to the channel structures 37 through the second contact plugs 39. The second contact plugs 39 may be disposed within a third interlayer insulating layer 4. The source structure 38 may include a conductive material, such as polysilicon or metal. The second contact plug 39 may include a conductive material, such as aluminum, copper, or tungsten. The third interlayer insulating layer 4 may include an insulating material, such as oxide or nitride.

According to the aforementioned structure, the bit line 33 may be disposed under the channel structures 37. Furthermore, the discharge interconnection structure 32 and the peripheral circuit PC may be disposed under the bit line 33. Accordingly, the bit line 33 may be used as a path for discharging charges generated when the channel structures 37 are formed.

For example, the bit line 33 may be disposed under the channel structures 37 and connected thereto. The discharge interconnection 32 may be disposed under the bit line 33 and connected thereto. The peripheral circuit PC may be disposed under the discharge interconnection 32 and connected thereto. In this case, charges generated when the channel structures 37 are formed may be discharged to the peripheral circuit PC through the bit line 33 and the discharge interconnection 32.

Referring to FIGS. 3A and 3B, the semiconductor device may further include landing pads 35.

The landing pads 35 may be disposed between the channel structures 37 and the first contact plugs 34. Each of the landing pads 35 may connect the channel structure 37 and the first contact plug 34. The landing pads 35 may be included in the interconnection. The landing pads 35 and the first contact plugs 34 may have the same width or different widths. For example, each of the landing pads 35 may have a greater width than each of the first contact plugs 34. In such a case, an alignment margin between the channel structures 37 and the first contact plugs 34 can be secured by the landing pads 35. Each of the channel structures 37 may be connected to the bit line 33 through the landing pad 35 and the first contact plug 34. For reference, the landing pads 35 may be directly connected to the bit line 33. The landing pads 35 may be disposed within the second interlayer insulating layer 3. The landing pads 35 may include polysilicon. The first contact plug 34, the landing pad 35, and the channel structure 37 may be aligned or might not be aligned.

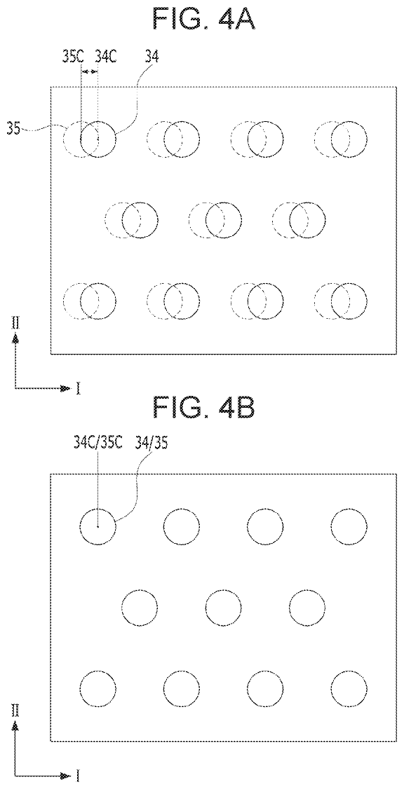

FIGS. 4A and 4B are diagrams for describing a semiconductor device according to an embodiment of the present disclosure. Hereinafter, contents redundant with the aforementioned contents are omitted and not described.

Referring to FIGS. 4A and 4B, first contact plugs 34 may be arranged in a first direction I and a second direction II that directionally intersects the first direction I. The first contact plugs 34 may be arranged so that centers 34C thereof are aligned with each other or may be arranged so that the centers 34C are offset with respect to each other. In a plane defined by the first direction I and the second direction II, each of the first contact plugs 34 may have a shape, such as a circle, an ellipse, or a polygon.

Landing pads 35 may be arranged in the first direction I and the second direction II. The landing pads 35 may be arranged so that centers 35C thereof are aligned with each other or may be arranged so that the centers 35C are offset with respect to each other. Each of the landing pads 35 may have substantially the same shape as the first contact plug 34 or have a shape different from that of the first contact plug 34. The sizes of the first contact plug 34 and the landing pad 35 may be substantially the same or may be different from each other.

The landing pads 35 may be disposed to correspond to the first contact plugs 34, respectively. A pair of the first contact plug 34 and the landing pad 35 disposed in a way to correspond to each other may be disposed in a way to be aligned with each other or not to be aligned with each other. Referring to FIG. 4A, the center 34C of the first contact plug 34 and the center 35C of the landing pad 35 might not be aligned with each other. The center 34C of the first contact plug 34 and the center 35C of the landing pad 35 might not be disposed at the same point, and may be offset with respect to each other in the first direction I. Referring to FIG. 4B, the center 34C of the first contact plug 34 and the center 35C of the landing pad 35 may be aligned with each other. The center 34C of the first contact plug 34 and the center 35C of the landing pad 35 may be disposed at the same point.

According to the aforementioned structure, an alignment margin can be secured and a degree of integration of semiconductor devices can be increased by efficiently disposing and connecting the first contact plugs 34 and the landing pads 35.

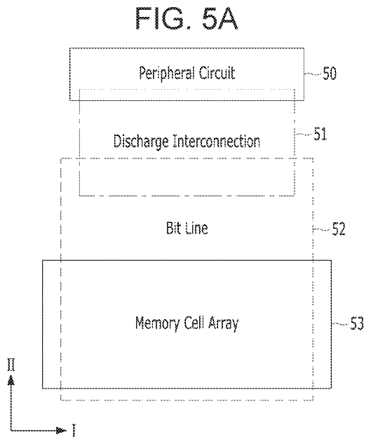

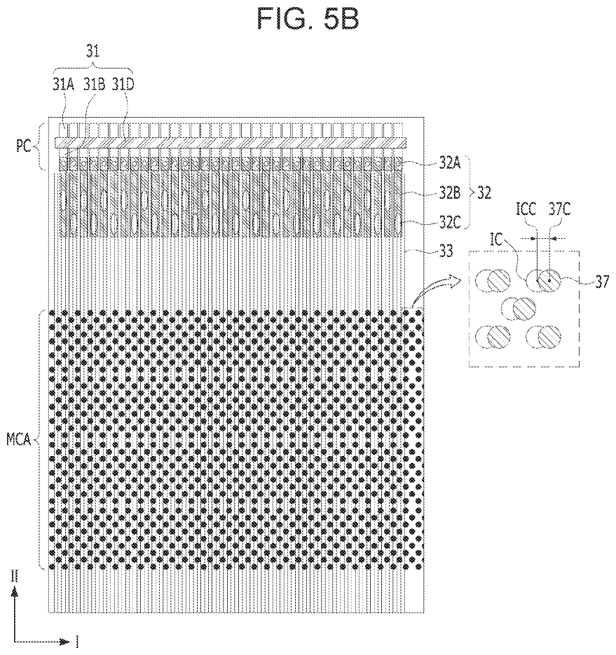

FIGS. 5A and 5B are diagrams for describing a semiconductor device according to an embodiment of the present disclosure. Hereinafter, contents redundant with the aforementioned contents are omitted and not described.

Referring to FIG. 5A, the semiconductor device may include a peripheral circuit 50, a discharge interconnection 51, a bit line 52, and/or a memory cell array 53, or may include a combination of them.

In a plane defined by a first direction I and a second direction II that directionally intersects the first direction I, the memory cell array 53 and the peripheral circuit 50 may be disposed to be adjacent to each other in the second direction II. The bit line 52 may be disposed to overlap the memory cell array 53 and may be extended in the second direction II toward the peripheral circuit 50. The discharge interconnection 51 may be disposed to overlap the peripheral circuit 50 and may be extended in the second direction II toward the memory cell array 53. The discharge interconnection 51 may be for connecting the peripheral circuit 50 and the bit line 52, and may overlap the bit line 52.

Referring to FIG. 5B, a semiconductor device may include a peripheral circuit PC, a memory cell array MCA, a discharge interconnection 32, an interconnection IC, and/or bit lines 33, or may include a combination of them.

The peripheral circuit PC may include transistors 31. The memory cell array MCA may include channel structures 37. The discharge interconnection 32 may include contact plugs 32A, wires 32B, and/or connection pads 32C, or may include a combination of them.

The transistors 31 may be arranged in a first direction I. Each of the transistors 31 may include a first junction 31A and a second junction 31B, and the transistors 31 may share a gate line 31D. The gate line 31D may be extended in the first direction I. The transistors 31 may be connected to the discharge interconnection 32 through the first junctions 31A or the second junctions 32A.

The discharge interconnection 32 may be disposed to overlap the peripheral circuit PC. The discharge interconnection 32 may be connected to active areas of the transistors 31. Each of the wires 32B may connect the contact plugs 32A, or may connect the contact plug 32A and the connection pad 32C. Each of the connection pads 32C may be connected to the bit line 33. Each of the contact plugs 32A may connect the wires 32B or may connect the wire 32B and the transistor 31. For example, the first junction 31A or second junction 31B of the transistor 31 may be connected to the contact plug 32A.

The memory cell array MCA may be disposed to be spaced apart from the peripheral circuit PC in a second direction II. The channel structures 37 may be arranged in the first direction I and the second direction II. The channel structures 37 may be arranged so that the centers 37C are aligned with each other or may be arranged so that the centers 37C are offset with respect to each other.

The center 37C of each of the channel structures 37 may be aligned or might not be aligned with the center ICC of an interconnection IC. The center 37C of the channel structure 37 and the center ICC of the interconnection IC that are mutually connected might not be disposed at the same point, and may be offset with respect to each other in the first direction I and/or the second direction II. The interconnection IC may include the first contact plugs or the landing pads or may include a combination of them. Accordingly, the center 37C of each of the channel structures 37 may be aligned or might not be aligned with the center of the first contact plug or the center of the landing pad.

The bit lines 33 may be disposed to overlap the memory cell array MCA. Each of the bit lines 33 may be connected to the channel structure 37. One bit line 33 may be connected to a plurality of the channel structures 37 in common, which are arranged in the second direction II. For example, the bit line 33 and the channel structure 37 may be connected through an interconnection structure. The bit lines 33 may be extended in the second direction II and connected to the discharge interconnection 32. The bit line 33 may be connected to the connection pad 32C, and may be connected to the transistor 31 through the connection pad 32C, the wire 32B, and the contact plug 32A.

According to the aforementioned structure, the bit line 33 and the peripheral circuit PC may be connected through the discharge interconnection 32. Furthermore, the bit lines 33 and the memory cell array MCA may be connected. Accordingly, a degree of integration of semiconductor devices can be increased by efficiently disposing and connecting the memory cell array MCA, the bit lines 33, the discharge interconnection 32, and the peripheral circuit PC.

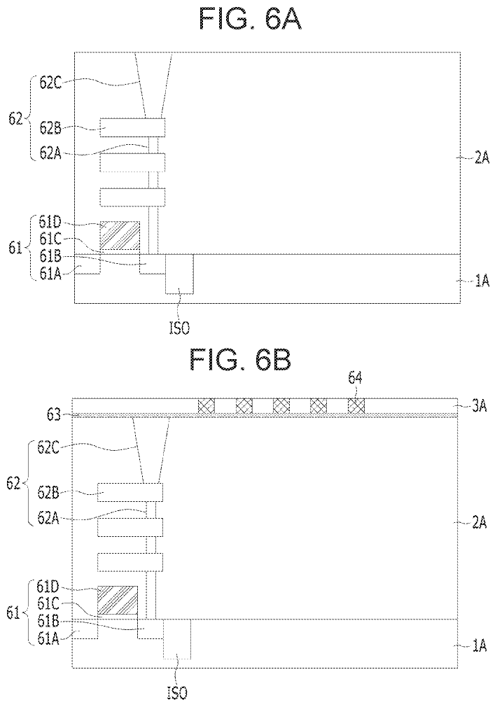

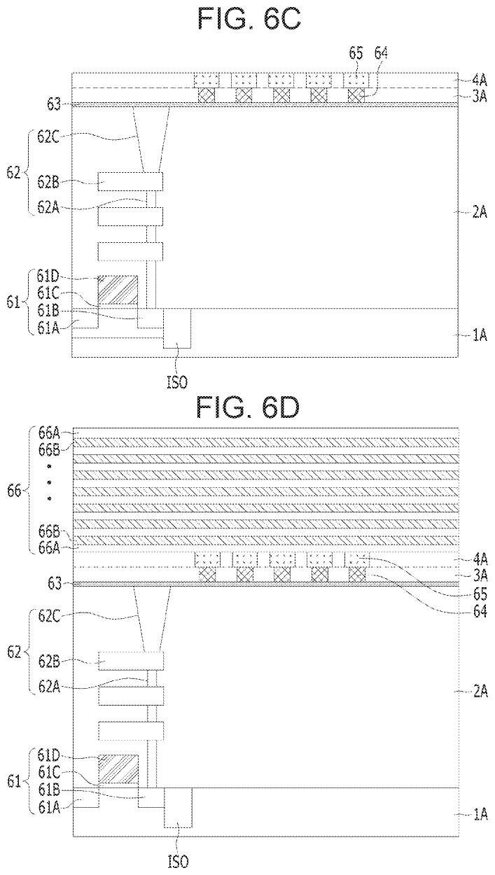

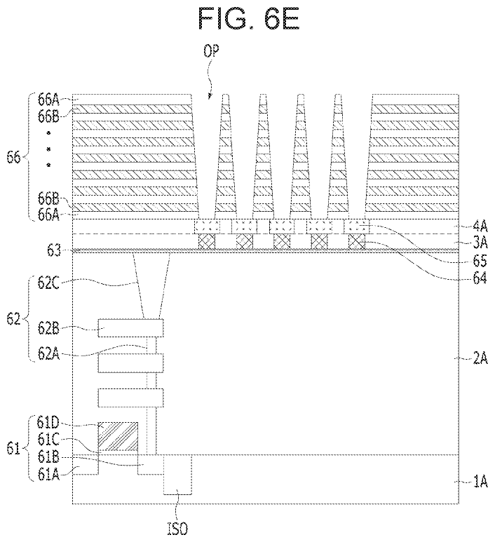

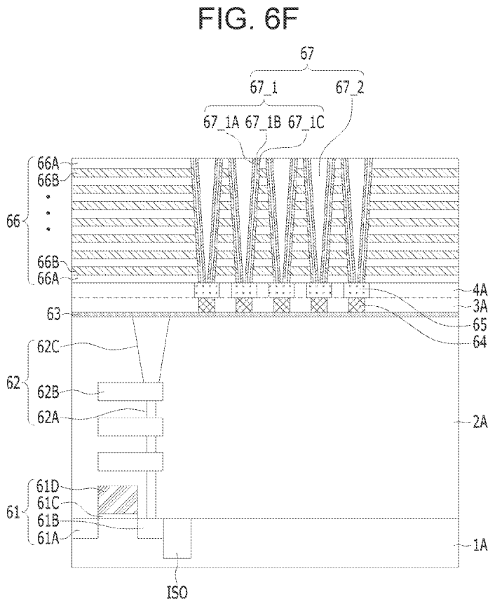

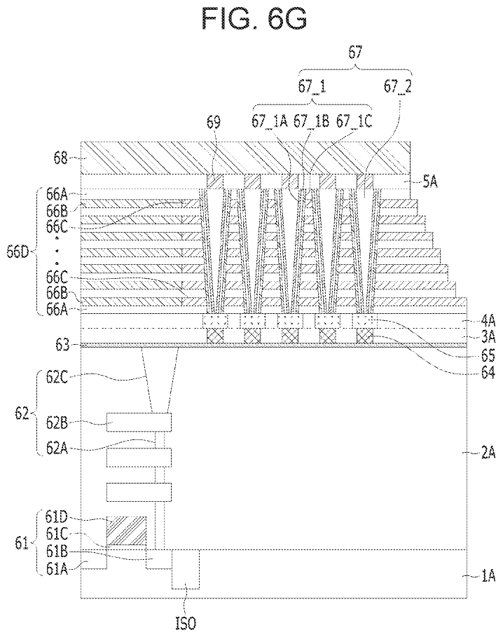

FIGS. 6A to 6G are diagrams for describing a method of manufacturing a semiconductor device according to an embodiment of the present disclosure. Hereinafter, contents redundant with the aforementioned contents are omitted and not described.

Referring to FIG. 6A, a peripheral circuit PC may be formed on a substrate 1A. An isolation layer ISO may be formed within the substrate 1. An active area may be defined by the isolation layer ISO. The peripheral circuit PC may include a transistor 61. The peripheral circuit PC may include a page buffer.

The transistor 61 may be included in the page buffer, and may be a high voltage transistor. The transistor 61 may include a first junction 61A, a second junction 61B, a gate insulating layer 61C, and a gate electrode 61D.

Next, a discharge interconnection 62 connected to the peripheral circuit PC may be formed. For example, the discharge interconnection 62 connected to the transistor 61 may be formed. The discharge interconnection 62 may be formed within a first interlayer insulating layer 2A.

The discharge interconnection 62 may include contact plugs 62A, wires 62B, and/or a connection pad 62C. The discharge interconnection 62 may be formed by combining the contact plugs 62A, the wires 62B, and/or the connection pad 62C. The first junction 61A or second junction 61B of the transistor 61 may be connected to the discharge interconnection 62. For example, each of the contact plugs 62A may connect the wires 62B, or may connect the wire 62B and the first junction 61A or the second junction 61B. The discharge interconnection 62 may include a conductive material, such as tungsten. The first interlayer insulating layer 2A may include an insulating material, such as nitride or oxide.

Referring to FIG. 6B, a bit line 63 connected to the discharge interconnection 62 may be formed. The bit line 63 may be formed on the discharge interconnection 62. The bit line 63 and the peripheral circuit PC may be connected by the discharge interconnection 62. For example, the bit line 63 and an active area of the transistor 61 may be connected by the discharge interconnection 62.

Next, an interconnection may be formed on the bit line 63. The interconnection may be for connecting the bit line 63 and channel structures to be formed in a subsequent process. For example, first contact plugs 64 may be formed on the bit line 63. The first contact plugs 64 may be formed within a second interlayer insulating layer 3A. The first contact plugs 64 may be electrically connected to the discharge interconnection 62 and the peripheral circuit PC by the bit line 63. The first contact plugs 64 may include a conductive material, such as tungsten. The second interlayer insulating layer 3A may include an insulating material, such as oxide or nitride.

Referring to FIG. 6C, landing pads 65 may be formed on the first contact plugs 64. First, a conductive layer may be formed on the first contact plugs 64. Next, the landing pads 65 may be formed by etching the conductive layer by using a mask pattern as an etch barrier. The landing pads 65 may be formed within a third interlayer insulating layer 4A.

The landing pads 65 may be connected to the first contact plugs 64, respectively. In this case, the landing pads 65 may be aligned or might not be aligned with the first contact plugs 64, respectively. The landing pads 65 may include polysilicon. The third interlayer insulating layer 4A may include an insulating material, such as an oxide or nitride.

Accordingly, an interconnection including the first contact plugs 64 and the landing pads 65 may be formed. For reference, the step of forming the landing pads 65 may be omitted.

Referring to FIG. 6D, a stack 66 may be formed on the landing pads 65. The stack 66 may be formed by alternately stacking first material layers 66A and second material layers 66B. For example, the first material layers 66A may include an insulating material, such as an oxide, and the second material layers 66B may include a sacrificial material, such as a nitride. Furthermore, for example, the first material layers 66A may include an insulating material, such as an oxide, and the second material layers 66B may include a conductive material, such as polysilicon, tungsten, molybdenum, etc. For reference, if the step of forming the landing pads 65 is omitted, the stack 66 may be formed on the first contact plugs 64. For example, the stack 66 may be formed to contact the tops of the first contact plugs 64.

Referring to FIG. 6E, openings OP that penetrate the stack 66 may be formed. The openings OP may expose the landing pads 65, respectively. If the step of forming the landing pads 65 is omitted, the openings OP may expose the first contact plugs 64, respectively. Each of the landing pads 65 may have a greater width than each of the first contact plugs 64. Accordingly, an alignment margin can be secured when the openings OP are formed.

Plasma may be used when the openings OP are formed. The stack 66 may be etched by ions of plasma. In this case, positive charges may be accumulated on surrounding layers, such as the stack 66 and the landing pads 65. A passage for discharging the accumulated charges is necessary because arcing occurs when the positive charges are accumulated.

According to an embodiment of the present disclosure, the landing pads 65, the first contact plugs 64, the bit line 63, and the discharge interconnection 62 may be used as a charge discharge passage. Accordingly, positive charges generated when the openings OP are formed may be discharged to the peripheral circuit PC via the bit line 63 and the discharge interconnection 62 through the landing pads 65 or the first contact plugs 64. For example, the positive charges may be discharged to the first junction 61A or second junction 61B of the transistor 61. Accordingly, the occurrence of arcing attributable to the process of forming the openings OP can be reduced, minimized, or prevented.

Referring to FIG. 6F, channel structures 67 may be formed within the openings OP. The channel structures 67 may be connected to the bit line 63, the discharge interconnection 62, and the peripheral circuit PC through the first contact plugs 64 or the landing pads 65. Each of the channel structures 67 may include a memory layer 67_1 or a channel layer 67_2. The memory layer 67_1 and the channel layer 67_2 may be sequentially formed within the opening OP. The channel layer 67_2 may include a semiconductor material, such as silicon or germanium. The memory layer 67_1 may include a tunneling layer 67_1A, a data storage layer 67_1B, or a blocking layer 67_1C or may include a combination of them.

For reference, electrode structures may be formed within the openings OP instead of the channel structures 67. The electrode structure may include an electrode layer that penetrates the stack 66, and may further include a memory layer that surrounds the external wall or internal wall of the electrode layer. The memory layer may include a variable resistance material.

Referring to FIG. 6G, a source structure 68 may be formed over the channel structures 67. The source structure 68 may be formed in various shapes, such as a plate and a line. Before the source structure 68 is formed, second contact plugs 69 may be formed on the channel structures 67. The second contact plugs 69 may be formed to be connected to the channel structures 67, respectively. Each of the second contact plugs 69 may connect the source structure 68 and the channel structure 67. The source structure 68 and the second contact plugs 69 may be formed within a fourth interlayer insulating layer 5A. The source structure 68 may include a conductive material, such as tungsten. The second contact plugs 69 may include a conductive material, such as aluminum, copper, or tungsten. The fourth interlayer insulating layer 5A may include an insulating material, such as an oxide or nitride.

Before the source structure 68 is formed, the second material layers 66B of the stack 66 may be substituted with third material layers 66C. For example, if the first material layers 66A include an insulating material and the second material layers 66B include a sacrificial material, the second material layers 66B may be substituted with conductive layers. The conductive layers may include a conductive material, such as polysilicon, tungsten, or molybdenum. Furthermore, for example, if the first material layers 66A include an insulating material and the second material layers 66B include a conductive material, the second material layers 66B may be silicided. Accordingly, a gate structure 66D including the first material layers 66A and the third material layers 66C that are alternately stacked may be formed.

Some of the second material layers 66B might not be substituted with the third material layers 66C. For example, a slit (not illustrated) that penetrates the stack 66 may be formed, and the second material layers 66B may be substituted with the third material layers 66C by removing the second material layers 66B through the slit. In this case, the second material layers 66B around the slit may be removed, and the second material layers 66B spaced apart from the slit may remain. In such a case, a part of the gate structure 66D may include the first material layers 66A and the second material layers 66B that are alternately stacked.

According to the aforementioned manufacturing method, after the discharge interconnection 62 and the bit line 63 are formed, the channel structures 67 may be formed. The channel structures 67 may be formed so that the channel structures are connected to the bit line 63 through the landing pads 65 or the first contact plugs 64. Accordingly, positive charges generated when the openings OP are formed may be discharged through the bit line 63, the discharge interconnection 62, and the peripheral circuit PC.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and/or change the embodiments in various ways without departing from the technical spirit of the present disclosure written in the claims. Such substitutions, modifications, and/or changes may be said to belong to the scope of the present disclosure.

What is claimed is:

1. A semiconductor device comprising:
a gate structure comprising conductive layers and insulating layers, which are alternately stacked;
channel structures penetrating the gate structure;
contact plugs disposed under the gate structure and connected to the channel structures, respectively;
a bit line connected to the channel structures through the contact plugs;
a peripheral circuit disposed under the bit line; and
a discharge interconnection that connects the bit line and the peripheral circuit.

2. The semiconductor device of claim 1, wherein:
the peripheral circuit comprises a transistor, and
the bit line and an active area of the transistor are connected by the discharge interconnection.

3. The semiconductor device of claim 2, wherein the transistor is a high voltage transistor.

4. The semiconductor device of claim 1, wherein:
the peripheral circuit comprises a page buffer, and
the discharge interconnection is connected to a high voltage transistor of the page buffer.

5. The semiconductor device of claim 1, further comprising landing pads connecting the channel structures and the contact plugs, respectively.

6. The semiconductor device of claim 5, wherein the landing pads are arranged in a first direction and a second direction that directionally intersects the first direction.

7. The semiconductor device of claim 5, wherein the landing pads comprise polysilicon.

8. The semiconductor device of claim 5, wherein the landing pads are aligned or not aligned with the contact plugs, respectively.

9. The semiconductor device of claim 5, wherein each of the landing pads has a greater width than each of the contact plugs.

10. The semiconductor device of claim 1, further comprising a source structure disposed over the channel structures.

11. The semiconductor device of claim 1, wherein the contact plugs are arranged in a first direction and a second direction that directionally intersects the first direction.

12. A method of manufacturing a semiconductor device, the method comprising:
forming a peripheral circuit;
forming a discharge interconnection connected to the peripheral circuit;
forming a bit line connected to the discharge interconnection;
forming contact plugs on the bit line;
forming a stack on the contact plugs;
forming openings that penetrate the stack and expose the contact plugs, respectively; and
forming channel structures within the openings, respectively.

13. The method of claim 12, wherein forming the openings comprises discharging charges to the peripheral circuit through the contact plugs, the bit line, and the discharge interconnection.

14. The method of claim 12, wherein:
the peripheral circuit comprises a transistor, and
the discharge interconnection is formed so that the bit line and an active area of the transistor are connected.

15. The method of claim 14, wherein the transistor is a high voltage transistor.

16. The method of claim 12, wherein:
the peripheral circuit comprises a page buffer, and
the discharge interconnection is formed to be connected to a high voltage transistor of the page buffer.

17. The method of claim 12, further comprising forming landing pads connected to the contact plugs, respectively.

18. The method of claim 17, wherein forming the landing pads comprises:
forming a conductive layer on the contact plugs before forming the stack; and
forming the landing pads by etching the conductive layer.

19. The method of claim 17, wherein each of the landing pads is formed to have a greater width than each of the contact plugs.

20. The method of claim 12, further comprising forming a source structure on the channel structures.
